(19) United States
(12) Patent Application Publication
(10) Pub. No.: US 2025/0347992 A1
(43) Pub. Date: Nov. 13, 2025

(54) IMPRINT METHOD, IMPRINT DEVICE, AND METHOD FOR PRODUCING ARTICLE

(71) Applicant: CANON KABUSHIKI KAISHA, Tokyo (JP)

(72) Inventor: KAZUHIRO SATO, Tochigi (JP)

(21) Appl. No.: 19/190,956

(22) Filed: Apr. 28, 2025

(30) Foreign Application Priority Data
May 7, 2024 (JP) 2024-075400

(51) Int. Cl. G03F 7/00

(52) U.S. Cl. CPC G03F 7/0002

(57) ABSTRACT

Provided is an imprint method which includes: a contact step of bringing a mould into contact with an imprint material on a substrate; a first irradiation step of irradiating the imprint material on the substrate with first light for curing the imprint material while the mould and the imprint material on the substrate are in contact with each other; a demolding step of separating the mould from the imprint material on the substrate; and a second irradiation step of irradiating, other than an imprint region in which an imprint process including the contact step, the first irradiation step, and the demolding step is performed, a skip region that is a region in which the imprint process is skipped with second light if the skip region exists on the substrate.

### BACKGROUND OF THE INVENTION

### Field of the Invention

The present invention relates to an imprint method, an imprint device, and a method for producing an article.

### Description of the Related Art

Imprint devices are being put into practical use as one of the lithography techniques for mass production of magnetic storage media and semiconductor devices. An imprint technique is a method for forming a pattern on a substrate by bringing a mould (mold) on which a fine circuit pattern has been formed into contact with a resin with which a substrate such as a silicon wafer or a glass plate is coated. For example, in forming a circuit pattern for a semiconductor device, the overlapping (alignment) accuracy between a circuit pattern already formed on a wafer and a circuit pattern to be formed therefrom is very important.

Japanese Patent No. 4964841 discloses a method for reducing an influence of the temperature of a wafer caused due to irradiation with light to cure a resin on the overlapping accuracy by preventing a region to be subjected to imprint from being adjacent to each other to improve the overlapping accuracy.

Here, in the technique disclosed in Japanese Patent No. 4964841, if a foreign particle is detected and a region which is not subjected to imprint exists, the influence of light which cures a resin on the adjacent regions changes. That is to say, if a region which is not subjected to imprint exists, the influence of a temperature on the surrounding region thereof changes and the overlapping accuracy deteriorates.

### SUMMARY OF THE INVENTION

Therefore, an embodiment of the present invention provides an imprint method which can maintain the overlapping accuracy well even if a region which is not subjected to an imprint process exists.

An imprint method according to an aspect of the present invention is an imprint method which includes: a contact step of bringing a mould into contact with an imprint material on a substrate; a first irradiation step of irradiating the imprint material on the substrate with first light for curing the imprint material while the mould and the imprint material on the substrate are in contact with each other; a demolding step of separating the mould from the imprint material on the substrate; and a second irradiation step of irradiating, other than an imprint region in which an imprint process including the contact step, the first irradiation step, and the demolding step is performed, a skip region that is a region in which the imprint process is skipped with second light if the skip region exists on the substrate.

Further features of the present invention will become apparent from the following description of exemplary embodiments with reference to the attached drawings.

### BRIEF DESCRIPTION OF THE DRAWINGS

FIG. 1 is a diagram showing a schematic configuration of an imprint device of a first embodiment.

FIG. 2 is a flowchart for describing the imprint method of the first embodiment.

FIG. 3 is a flowchart for describing the imprint method of the first embodiment.

FIGS. 4A to 4C are diagrams showing problems in the first embodiment.

FIG. 5 is a diagram for explaining an example of a method for calculating an illuminance in a second embodiment.

FIGS. 6A to 6F are schematic diagrams for explaining a method for producing an article.

### DESCRIPTION OF THE EMBODIMENTS

Embodiments will be described in detail below with reference to the accompanying drawings. The following embodiments are not intended to limit the scope of the claims. Although the embodiments describe a plurality of features, not all of these plurality of features are essential to the invention and the plurality of features may be combined in any desired manner. Furthermore, in the accompanying drawings, the same or similar constituent elements are denoted by the same reference numerals and duplicate explanations thereof will be omitted.

### First Embodiment

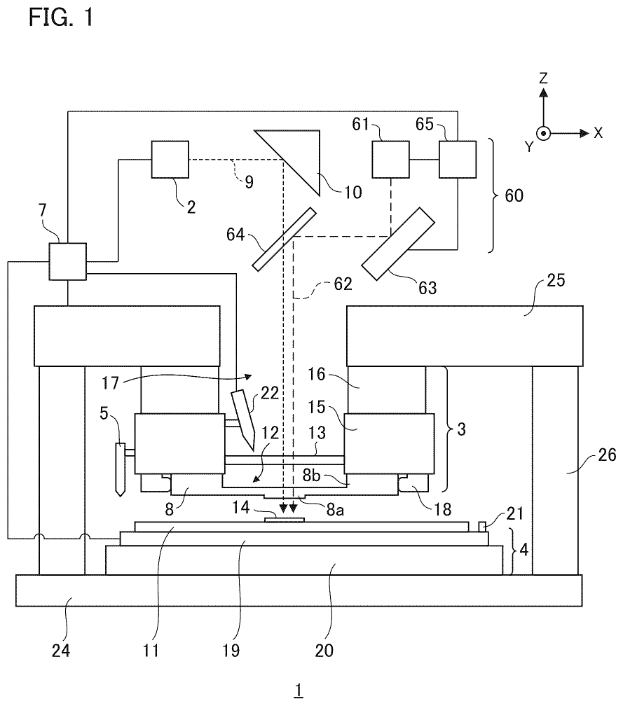

FIG. 1 is a diagram showing a schematic configuration of an imprint device 1. A configuration of the imprint device 1 according to this embodiment will be described below with reference to FIG. 1.

The imprint device 1 is a device (a lithography device) which is used for producing a device such as a semiconductor device serving as an article. The imprint device 1 functions as a device which performs an imprint process of forming a pattern of a resin (an imprint material) on a wafer 11 by pressing a mold against an uncured resin (an uncured imprint material) on the wafer 11 and irradiating it with light. That is to say, the imprint process is a process of sequentially forming a pattern of an imprint material in a plurality of imprint regions on a substrate using a mould having a pattern portion. The imprint process will be described in detail later.

In the embodiment, it is assumed that the imprint device is an imprint device in which a photocuring method is adopted. Furthermore, in FIG. 1, a Z axis is parallel to an optical axis of an illumination system which irradiates the imprint material on the wafer 11 with ultraviolet (UV) light and X and Y axes are orthogonal to each other in a plane perpendicular to the Z axis.

The imprint device 1 includes a curing light irradiation unit 2, a mold holding mechanism 3, a wafer stage 4, a coating unit 5, a light transmitting member 13, alignment measurement system (position deviation detection unit) 22, a heating mechanism 60, an adjuster 63, an irradiation control unit 65, and a control unit 7.

The curing light irradiation unit 2 irradiates a mold 8 with light via a mirror 10 during the imprint process. Specifically, the mold 8 is irradiated with ultraviolet light 9. Although not shown, the curing light irradiation unit 2 includes a light source and an optical element configured to adjust the ultraviolet light 9 radiated from the light source to light suitable for imprinting. Although the curing light irradiation unit 2 is installed to adopt the photocuring method in the embodiment, for example, if a thermal curing method is adopted, a heat source unit for curing a thermosetting resin is installed instead of the curing light irradiation unit 2.

The mold (mould) 8 has an outer circumferential shape being an angular shape and includes a pattern portion (for example, a concave and convex pattern to be transferred such as a circuit pattern) 8a formed three-dimensionally on a surface thereof facing the wafer 11. Furthermore, the mold 8 is made of a material such as quartz through which the ultraviolet light 9 can be transmitted. In addition, the mold 8 may have a shape having a cavity (a concave portion) 8b configured to facilitate deformation of the mold 8 in a surface thereof irradiated with the ultraviolet light 9. The cavity 8b has a circular planar shape and a thickness (depth) thereof is set appropriately in accordance with a size and a material of the mold 8.

Also, the light transmitting member 13 in which a space 12 surrounded by a part of the opening region 17 and the cavity 8b is formed as a sealed space is installed in an opening region 17 in the mold holding mechanism 3 which will be described later and there can also be a configuration in which the pressure in the space 12 is controlled using a pressure adjustment device (not shown). For example, when the mold 8 is pressed against an imprint material (resin) 14 on the wafer 11, by setting the pressure in the space 12 to be higher than the outside using the pressure adjustment device, the pattern portion 8a is bent in a convex shape toward the wafer 11. For this reason, the pattern portion 8a is in contact with the imprint material 14 from a center portion of the pattern portion 8a. Thus, the trapping of gas (air) between the pattern portion 8a and the imprint material 14 can be suppressed and every corner of the uneven portions of the pattern portion 8a can be filled with the imprint material 14.

The mold holding mechanism 3 includes a mold chuck 15 which attracts and holds the mold 8 using a vacuum suction force or an electrostatic force and a mold drive mechanism 16 which holds the mold chuck 15 and moves the mold 8 (the mold chuck 15). The mold chuck 15 and the mold drive mechanism 16 include the opening region 17 at a center portion thereof (inner side) so that the wafer 11 is irradiated with the ultraviolet light 9 radiated from the light source of the curing light irradiation unit 2. In addition, the mold holding mechanism 3 includes a magnification correction mechanism (mold deformation mechanism) 18 which corrects a shape of the mold 8 (the pattern portion 8a) by applying an external force or displacement to the side of the mold 8 on the holding side of the mold 8 in the mold chuck 15. The mold deformation mechanism 18 can align a shape of the pattern portion 8a formed in the mold 8 with a shape of a pattern on the wafer side formed in advance on the wafer 11 by changing a shape of the mold 8.

The mold drive mechanism 16 moves the mold 8 in a Z-axis direction to selectively press the mold 8 against or separate the mold 8 from the imprint material 14 on the wafer 11. As an actuator which can be adopted for the mold drive mechanism 16, for example, there is a linear motor or an air cylinder. Furthermore, in order to accommodate high-precision positioning of the mold 8, the mold 8 may be configured of a plurality of drive systems such as a coarse movement drive system and a fine movement drive system. In addition, there can also be a configuration in which the mold 8 has a position adjustment function not only in the Z-axis direction, but also in the X-axis direction or the Y-axis direction, and the 0 (rotation around the Z-axis) direction, a tilt function of correcting the inclination of the mold 8, and the like. Although the pressing (contact) and separating operations of the imprint device 1 may be realized by moving the mold 8 in the Z-axis direction as described above, this may be achieved by moving the wafer stage 4 in the Z-axis direction or by moving both of them relatively.

The wafer (substrate) 11 is, for example, a single crystal silicon wafer or a Silicon on Insulator (SOI) wafer. A surface to be processed of the wafer 11 is coated with a UV curing resin (hereinafter referred to as an “imprint material”) 14 which is formed using the pattern portion 8a formed in the mold 8.

The wafer stage 4 holds the wafer 11 and performs alignment of the mold 8 with the imprint material 14 when pressing the mold 8 against the imprint material 14 on the wafer 11. The wafer stage 4 includes a wafer chuck (wafer holding unit) 19 which holds the wafer 11 using a suction force and a stage drive mechanism 20 which holds the wafer chuck 19 using a mechanical unit and can be moved in the XY plane.

The wafer chuck 19 includes a plurality of suction units which enable the rear surface of the wafer 11 to be suction-held in a plurality of regions. Although not shown, these suction units are each connected to a separate pressure adjustment device. The pressure adjustment device adjusts the pressure between the wafer 11 and the suction units so that the pressure is decreased and generates a suction force, thereby holding the wafer 11 on a surface of the wafer chuck 19, while also allowing a pressure value (a suction force) to be changed independently at each suction unit. The number of divisions (the number of installations) of the suction units is not particularly limited and may be any number.

Also, the wafer stage 4 has a reference mark 21 on a surface thereof which is used at the time of aligning the mold 8. The stage drive mechanism 20 may adopt, for example, a linear motor as an actuator. The stage drive mechanism 20 may also be composed of a plurality of drive systems such as a coarse movement drive system and a fine movement drive system for each of the X-axis and Y-axis directions. In addition, there can also be a configuration in which the stage drive mechanism 20 has a drive system for adjusting the position in the Z-axis direction, a position adjustment function in the 0 direction of the wafer 11, a tilt function for correcting the inclination of the wafer 11, and the like. The wafer stage 4 is an alignment unit configured to align the wafer 11 with the mold 8.

The coating unit 5 coats the wafer 11 with the imprint material 14 that is an uncured resin. Here, the imprint material 14 is a light curing resin which has the property of being cured when receiving the ultraviolet light 9 and is appropriately selected in accordance with various conditions of the semiconductor device production process or the like. Furthermore, an amount of the imprint material 14 discharged from a discharge nozzle of the coating unit 5 is also determined appropriately in accordance with a desired thickness of the imprint material 14 to be formed on the wafer 11, a density of the pattern to be formed, and the like.

The alignment measurement system 22 is, for example, for wafer alignment and measures the positional deviation in the X-axis and Y-axis directions between an alignment mark formed on the wafer 11 and an alignment mark formed on the mold 8.

The heating mechanism 60 radiates light 62 to heat the imprint region (pattern formation region, shot region) on the wafer 11. Thus, the imprint region on the wafer 11 is deformed into a target shape. Here, the imprint region refers to a region in which the pattern of the pattern portion 8a is formed in the imprint material 14 in one imprint process. The heating mechanism 60 corrects a shape of the imprint region, thereby reducing a difference in shape between the imprint region of the wafer 11 and the pattern portion 8a.

The heating mechanism 60 includes a light source 61, the adjuster 63 which adjusts an illuminance distribution and an irradiation time period of the light 62 emitted from the light source, and a mirror 64 which deflects light from the adjuster 63 toward the wafer 11. In addition, the heating mechanism 60 includes a light collecting optical system (not shown) which collects light emitted from the light source 61 and a uniform illumination optical system (not shown) which uniformizes the intensity of light from the light collecting optical system. The uniform illumination optical system includes, for example, an optical element such as a micro-lens array (not shown).

The light (third light) 62 is light having a wavelength at which the imprint material 14 is not cured. In addition, the light 62 is also light having a wavelength for compensating for the difference in shape between the imprint region on the wafer 11 and the pattern portion 8a. For example, it is preferable that the light 62 be light of a wavelength different from the wavelength of the ultraviolet light 9 and be light existing in the wavelength band of 400 to 1200 nm. Particularly, light in a wavelength band which is hardly absorbed by the mold 8 but is easily absorbed by the wafer 11 is preferable. If there is light used in the imprint device 1 in addition to the ultraviolet light 9, it is preferable that the light have a wavelength other than the wavelength band of a corresponding light. Alternatively, light in a wavelength band of 200 to 400 nm may be used as long as the light is in a wavelength band to which the imprint material 14 is not easily sensitive.

As the adjuster 63, for example, a Digital Micro-Mirror Device (DMD) is used. The DMD has a plurality of micro-mirrors (not shown) by which light is reflected and the presence or absence of the irradiation with the light 62 is selected by tilting each of the micro-mirrors at an angle of −12 degrees (ON state) or +12 degrees (OFF state) with respect to the micro-mirror array surface.

The irradiation control unit 65 has a CPU and selectively controls the switching of the ON state or the OFF state of each of the micro-mirrors on the basis of irradiation amount distribution data instructed from the control unit 7 which will be described later. The irradiation amount distribution data includes information regarding a length of time (timing) for which the imprint region is irradiated with light from each of the micro-mirrors in the ON state and information regarding an illuminance distribution of an imprint region formed at the same time. The more micro-mirrors which are in the ON state and the longer the irradiation time with the light 62, the greater the amount of radiation to the imprint region. That is to say, an amount of heat applied to the imprint region increases.

Instead of adjusting the amount of irradiation by changing the irradiation time, the heating mechanism 60 may change the amount of irradiation by changing the intensity of the light 62. By applying an irradiation amount distribution using the heating mechanism 60, a heat distribution is formed in one imprint area. In this way, the region to be processed of the wafer 11 is locally deformed into a desired shape. The irradiation control unit 65 further controls the timing of the emission of the light 62. As the adjuster 63, a liquid crystal device in which the irradiation amount distribution can be changed by individually controlling a voltage applied to a plurality of liquid crystal elements may be used. The mirror 64 is also disposed on an optical path of the ultraviolet light 9. The mirror 64 is, for example, a dichroic mirror through which the ultraviolet light 9 is transmitted and by which the light 62 is reflected.

The control unit 7 may control an operation, adjustment, and the like of each constituent element of the imprint device 1. The control unit 7 is composed of, for example, at least one computer or the like including a CPU, a memory, and the like, is connected to each constituent element of the imprint device 1 via a line, and may control each constituent element in accordance with a program or the like. The control unit 7 may be configured integrally with other parts of the imprint device 1 (in a common housing) or may be configured separately from the other parts of the imprint device 1 (in a separate housing).

Also, the imprint device 1 includes a base plate 24 on which the wafer stage 4 is placed, a bridge plate 25 which fixes the mold holding mechanism 3, and a pillar 26 which extends from the base plate 24 and supports the bridge plate 25. Furthermore, although not shown, the imprint device 1 includes a mold transport mechanism which transports the mold 8 from the outside of the device to the mold holding mechanism 3 and a wafer transport mechanism (not shown) which transports the wafer 11 from the outside of the device to the wafer stage 4.

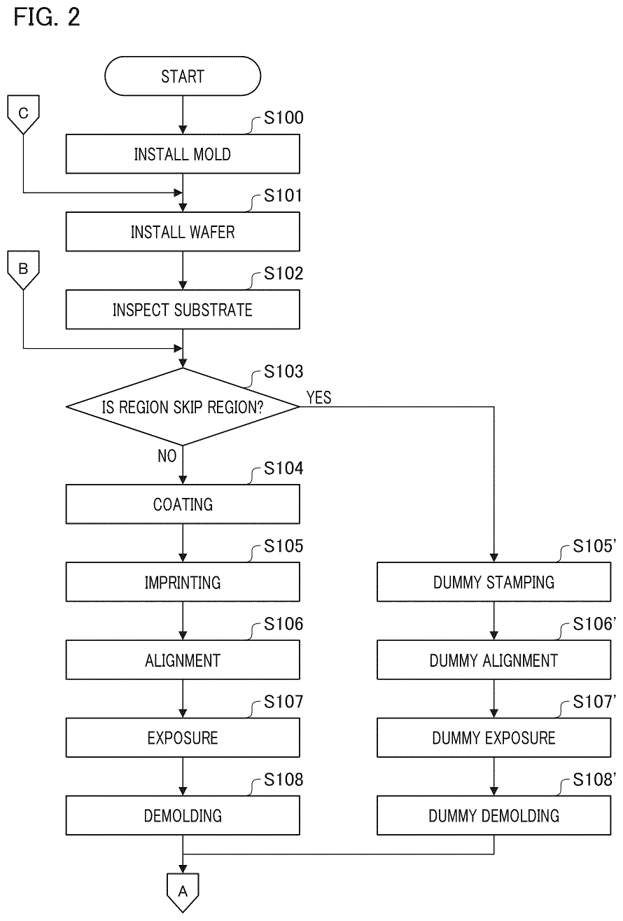

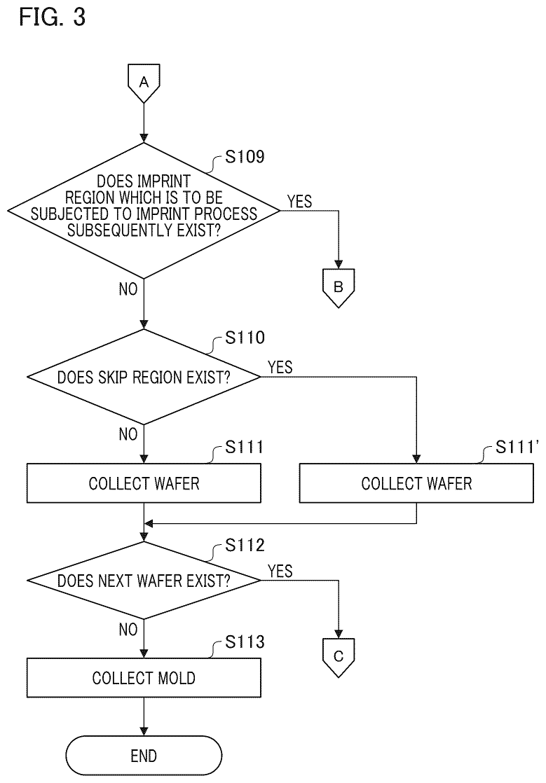

An imprint method performed by the imprint device 1 will be described below with reference to FIGS. 2 and 3. FIGS. 2 and 3 are flowcharts for describing the imprint method performed by the imprint device 1 according to the first embodiment. Each operation (process) shown in the flowcharts of FIGS. 2 and 3 is controlled by the control unit 7 of the imprint device 1 executing a computer program stored in a memory or the like. Furthermore, each process (step) is represented by adding an S to the beginning of the step, thereby abbreviating the notation of the process (step).

In S100, the control unit 7 controls a mold transport system to transport the mold 8 designated for that lot from the mold stocker to the mold holding mechanism 3 and fix it to the mold holding mechanism 3.

In S101, the control unit 7 controls the wafer transport system to transport the wafer 11 that is a process target from a wafer carrier to the wafer chuck 19.

In S102, before subjecting a plurality of imprint regions on the wafer 11 to the imprint process, the control unit 7 uses a foreign particle inspection device (not shown) to inspect whether foreign particles are present on each imprint region (pattern formation region). In the embodiment, the foreign particle inspection device is disposed in the imprint device 1.

In S103, the control unit 7 determines whether an imprint region in which the imprint process will be performed from now is to be a skip region (determination step). The skip region is a region in which the mold 8 is not brought into contact with the imprint material 14 on the wafer 11 and the imprint process is skipped so that a pattern of the imprint material is not formed on the imprint region. In other words, the skip region is a region other than the imprint region in which the imprint process, which includes at least a contact step, a first irradiation step, and a demolding step which will be described below, is performed and in which the imprint process is skipped. As a determination concerning whether to designate a region as a skip region, first, based on the inspection result of S102, it is determined whether a foreign particle has been detected in an imprint region in which the imprint process will be performed from now on the basis of the detection result of the foreign particle inspection device.

If a foreign particle is not detected on the imprint region in which the imprint process will be performed from now as a result of the determination, the process proceeds to S104. On the other hand, if a foreign particle is detected on the imprint region in which the imprint process will be performed from now, from information such as a position, a size, and the like of the foreign on the wafer 11, it is further determined whether the pattern portion 8a in the mold 8 is damaged or likely to be damaged. If it is determined that the pattern portion 8a of the mold 8 is damaged or is likely to be damaged due to a foreign particle as a result of the determination, the imprint region in which the imprint process will be performed from now is determined to be a skip region and the process proceeds to S105′. As the determination process if a foreign particle is detected on the imprint region in which the imprint process will be performed from now, for example, it may be possible to determine whether a detected foreign particle is to be a skip region by determining whether a size of the detected foreign particle is equal to or smaller than a predetermined size. On the other hand, if the pattern portion 8a of the mold 8 is not damaged or is not likely to be damaged due to a foreign particle, the imprint region in which the imprint process will be performed from now is not determined to be a skip region and the process proceeds to S104.

As described above, detection of a foreign particle present in the imprint region on the wafer 11 in the embodiment is performed using a foreign particle inspection device (foreign particle detection unit) in the imprint device 1. Here, the detection is not limited thereto and may be performed using an external foreign particle inspection device. In this case, an identification number of the wafer and information regarding a position and a size of a foreign particle on the wafer 11 which are acquired using the external foreign particle inspection device may be transmitted to the imprint device 1 and stored in a storage medium (not shown) such as a memory and a secondary storage device included in the imprint device 1. In this case, the control unit 7 may determine whether to set the imprint region in which the imprint process will be performed from now as a skip region on the basis of each piece of information in the foreign particle stored in the storage medium in S103. Furthermore, based on each piece of information in the foreign particle stored in the storage medium, it may be determined that the predetermined imprint region is set to a skip region before the imprint process. In other words, the skip region may not be the imprint region in which the imprint process will be performed from now.

First, the process performed on the imprint region that was not determined to be a skip region in the process of S103 will be described below.

In S104, the control unit 7 moves the wafer stage 4 so that the wafer stage 4 is directly below the coating unit 5. After that, the control unit 7 performs control so that the coating unit 5 applies (supplies) the imprint material 14 to an imprint region on the wafer 11 in which the imprint process will be performed from now (coating step).

In S105, the control unit 7 drives the wafer stage 4 to dispose the imprint region which has been coated with the imprint material 14 of the wafer 11 at a predetermined position directly below the mold holding mechanism 3. After that, the control unit 7 controls the mold holding mechanism 3 to drive the mold 8 in the Z direction, thereby bringing the pattern portion 8a formed on the mold 8 into contact with the imprint material 14 on the wafer 11 (contact step). That is to say, the pattern portion 8a formed on the mold 8 is pressed (stamped) onto the imprint material 14 on the wafer 11.

In S106, the control unit 7 simultaneously observes a mark on the wafer side (not shown) and a mark on the mold side (not shown) using the alignment measurement system 22. Furthermore, in order to correct any deviation in the relative position obtained through the observation, the wafer stage 4 is driven to align the wafer 11 and the mold 8 so that the amount of relative position deviation falls within a predetermined tolerance (alignment step). In addition, in S106, in parallel with the alignment using the wafer stage, a process of deforming the mold 8 using the mold deformation mechanism 18 to correct the shape of the mold 8 is performed (shape correction step). In addition, the imprint region on the wafer 11 is irradiated with the light 62 from the light source 61 of the heating mechanism 60 to deform the wafer 11, thereby correcting the shape of the wafer 11 (fourth irradiation step). Each of the shape correction step and the fourth irradiation step may be performed in parallel with the alignment step or any step may be performed first, and not in parallel, as long as they are completed before the start of S107.

In S106, the mold deformation mechanism 18 and the heating mechanism 60 correct deformations of magnification components, trapezoid components, parallelogram components, or the like caused due to the influences of a series of semiconductor device producing processes or the like.

In the shape correction step, the mold deformation mechanism 18 corrects the mold 8 on the basis of, for example, the results of observation of a mark on the side of the plurality of wafers 11 and a mark on the side of the mold 8 using the alignment measurement system 22. Specifically, the control unit 7 calculates the magnification component, the trapezoid component, the parallelogram component or the like on the basis of the results of the alignment measurement system 22 and calculates the external force or displacement applied to the side of the mold 8, thereby allowing the mold deformation mechanism 18 to correct the shape of the pattern portion 8a.

In the fourth irradiation step, the heating mechanism 60 irradiates the imprint region of the wafer 11 with the light 62 from the light source 61 so that the heating distribution in the imprint region is a desired distribution, that is, so that the difference in shape between the imprint region of the wafer 11 and the pattern portion 8a is reduced. Information regarding the difference in shape between the imprint region of the wafer 11 and the pattern portion 8a is acquired, for example, using an external measuring device and the control unit 7 acquires the information regarding the difference in shape by calculating an illuminance distribution for reducing the difference in shape on the basis of the acquired information regarding the difference in shape. For example, if the difference in shape includes a deformation which occurs to include a trapezoidal component, the heating mechanism 60 irradiates the imprint region with the light 62 so that the amount of heat in the imprint region decreases linearly in a direction from a short side toward a long side. Thus, heat can be applied to the wafer 11 so that the temperature in the imprint region decreases linearly in the direction from the short side toward the long side and the imprint region which has a difference in shape occurring to include a trapezoidal component can be deformed to have a target shape.

In S107, the control unit 7 controls the curing light irradiation unit 2 to radiate the ultraviolet light 9 from the rear surface of the mold 8 (an upper surface of the imprint device) while the pattern portion 8a of the mold 8 and the imprint material 14 are in contact with each other. The ultraviolet light 9 radiated by the curing light irradiation unit 2 is transmitted through the mold 8 and is radiated onto the imprint material 14. In this way, the curing light irradiation unit 2 can cure the imprint material 14 by irradiating the imprint material 14 with the ultraviolet light 9 (first irradiation step). In the embodiment, the ultraviolet light 9 irradiated in the step (the first irradiation step) of S107 is assumed to be first light.

In S108, after the imprint material 14 has been cured, the control unit 7 causes the mold holding mechanism 3 to widen the gap between the wafer 11 and the mold 8 and separate the mold 8 from the cured imprint material 14 (demolding step). Thus, a pattern of the imprint material 14 is formed on the wafer 11. That is to say, the pattern formed on the pattern portion 8a of the mold 8 is transferred to the imprint material 14 on the imprint region.

At this time, the control unit 7 controls the wafer chuck 19 to partially decrease the pressure values of the suction units with respect to a region corresponding to the imprint region which has been subjected to the imprint process. This is provided to reduce a force required for separating the mold 8 from the pattern of the imprint material 14 and to prevent damage to the formed pattern of the imprint material 14. At the same time, the wafer 11 is adsorbed to the wafer chuck 19 with a pressure to the extent that the wafer 11 is not completely separated from the wafer chuck 19 except for the imprinted region. Thus, this prevents the wafer 11 from separating from the wafer chuck 19 and partially decreases the pressure value, thereby reducing the force required for separating the mold 8 from the pattern of the imprint material 14. Explaining in more detail, as the driving using the mold holding mechanism 3 is performed, the imprinted region of the wafer 11 and a surrounding region thereof temporarily lift up and the bending deformation occurring in the wafer 11 reduces the force pulling the mold 8 away from the pattern of the imprint material 14. It is preferable that the operation (process) of partially decreasing the pressure values of the suction units with respect to a region corresponding to the imprint region be performed simultaneously or in conjunction with the demolding in S108.

In this way, for an imprint region which is determined not to be a skip region in S103, as the imprint process, the coating step, the contact step, the alignment step, the first irradiation step, and the demolding step are performed in that order to form a pattern of imprint material on the wafer 11. In parallel with the alignment step, the shape correction step and the fourth irradiation step are also performed. In the embodiment, the imprint process also includes the shape correction step and the fourth irradiation step.

In S109, the control unit 7 determines whether an imprint region which is to be subjected to the imprint process subsequently exists. If it is determined that an imprint region which is to be subjected to the imprint process subsequently exists as the result of the determination, the process returns to S103 and the same processes are sequentially performed. That is to say, the imprint device 1 sequentially drives the wafer stage 4 and repeatedly performs the imprint process for all imprint regions designated for that lot, thereby transferring the concave and convex pattern of the pattern portion 8a in the mold 8 across the entire surface of the wafer 11. On the other hand, if it is determined that an imprint region is to be subjected to the imprint process subsequently does not exist, the process proceeds to S110.

In S110, it is determined whether any region exists among all imprint regions on the wafer 11 which has been determined to be a skip region in S103 and which has been subjected to the processes of S105′ to S108′ (skip process). As a result of the determination, if it is determined in S103 that the region is the skip region and a region which has been subjected to the processes of S105′ to S108′ exists, the process proceeds to S111. On the other hand, if it is determined in S103 that the region is the skip region and a region which has been subjected to the processes of S105′ to S108′ exists, the process proceeds to S111′.

In S111, the control unit 7 controls the wafer transport mechanism to collect the wafer 11 which has been subjected to the imprint process (the concave and convex pattern of the pattern portion 8a in the mold 8 has been transferred to the entire surface of the wafer 11) which is placed on the wafer chuck 19. The wafer 11 after collection is stored in a wafer storage case.

In S112, the control unit 7 determines whether another wafer on which a pattern of the imprint material 14 is to be formed exists, that is, whether another wafer on which an imprint process similar to the process flow shown in FIG. 1 is to be performed exists. If it is determined that another wafer on which the pattern of the imprint material 14 is to be formed exists as the result of the determination, the process returns to S101 and the same processes are performed sequentially. On the other hand, if another wafer on which the pattern of the imprint material 14 is to be formed does not exists, the process proceeds to S113.

In S113, the control unit 7 controls the mold transport mechanism to collect the mold 8 held in the mold chuck 15. After that, the process ends.

The process performed for the skip process will be explained below. The process for the skip region (skip process) is a process which is performed when it is determined in S103 that the predetermined imprint region is the skip region and refers to the processes of S105′ to S108′. Furthermore, another feature is that, when the skip process is performed, the process of S111′ is performed. For this reason, the other explanations of the same sequence if the skip process is not performed will be omitted.

In S105′, the control unit 7 performs dummy stamping that is a stamping operation, without coating with the imprint material 14 (first movement step). The dummy stamping is a process in which the wafer stage 4 is driven to dispose the imprint region (skip region) of the wafer 11 at a predetermined position directly below the mold holding mechanism 3 and the mold 8 is driven in the Z direction to bring the mold 8 close to the imprint region of the wafer 11. In the dummy stamping, the pattern portion 8a of the mold 8 is not brought into contact with the wafer 11. If the wafer 11 and the mold 8 come into contact with each other without the imprint material 14, they are likely to be damaged. Thus, it is preferable that the wafer 11 and the mold 8 do not come into contact with each other.

In S106′, the control unit 7 performs a dummy alignment. Here, in S106′, the wafer 11 and the mold 8 do not need to be aligned with high precision. Thus, alignment using the alignment measurement system and the deformation of the mold using the mold deformation mechanism 18 are not performed. Here, only irradiation with the light 62 from the heating mechanism 60 is performed (third irradiation step). With the wafer 11 and the mold 8 in close proximity, the heating mechanism 60 irradiates the wafer 11 with the light 62 of the same wavelength, illuminance, and illuminance distribution as in S106 for the same period of time. In other words, the irradiation time of the light 62 that is the third light in the third irradiation step performed in S106′, and the wavelength, the illuminance, and the illuminance distribution of the light 62 are the same as those in the fourth irradiation step performed in S106. In this way, the light 62 irradiated in S106′ has a wavelength which does not cure the imprint material, as in the fourth irradiation step.

In S107′, the control unit 7 controls the curing light irradiation unit 2 to irradiate the ultraviolet light 9 from the back surface of the mold 8 and performs a dummy exposure in which the imprint area (skip area) of the wafer 11 is irradiated with the ultraviolet light 9 which has been transmitted through the mold 8 (second irradiation process). In this way, it is assumed that, other than the imprint region in which the imprint process including the contact step, the first irradiation step, and the demolding step is performed, a skip region that is a region in which the imprint process is skipped is irradiated with second light if the skip region exists on the wafer 11. The dummy exposure is performed with the mold 8 and the wafer 11 in close proximity. In the embodiment, the ultraviolet light 9 irradiated in the step (the second irradiation step) of S107′ is assumed to be the second light. Furthermore, in the dummy exposure, the wafer 11 is irradiated with light of the same wavelength, illuminance, and illuminance distribution as the ultraviolet light 9 used in S107 for the same period of time. In other words, the irradiation time of the ultraviolet light 9 that is the second light in the second irradiation step performed in S107′ and the wavelength, the illuminance, and the illuminance distribution of the ultraviolet light 9 are the same as those in the first irradiation step performed in S107. In this way, the ultraviolet light 9 irradiated in S107′ is light which has a wavelength which cures the imprint material in the same manner as in the first irradiation step.

In S108′, the control unit 7 controls the mold holding mechanism 3 to widen the gap between the wafer 11 and the mold 8, thereby performing dummy demolding (second movement process). Furthermore, in S108′, as in S108, simultaneously with or in conjunction with the dummy demolding operation, the control unit 7 performs a process of partially decreasing the pressure value (suction pressure) of the suction units on the wafer chuck 19 corresponding to the imprint region (skip region) which is subjected to a dummy exposure (pressure control process).

In S111′, the control unit 7 controls the wafer transport mechanism to collect the wafer 11 which has been subjected to the skip process and is placed on the wafer chuck 19. At this time, the wafer 11 collected in S111′ is stored in a wafer storage case different from that of the wafer collected in S111.

It is preferable that the time required for each of the steps (S105′ to S108′) of the skip process performed on the skip region is the same as or substantially the same as the time required from S105 to S108.

In this way, the imprint region determined to be a skip region in S103 is not subjected to the coating step, the contact step, the alignment step, the first irradiation step, and the demolding step. Furthermore, in the embodiment, as described above, the first movement step is performed before the second irradiation step and the second movement step is performed after the second irradiation step. In addition, the pressure control step is performed after the second irradiation step. Moreover, the third irradiation step is performed after the first movement step and before the second irradiation step. Furthermore, the fourth irradiation step is performed before the first irradiation step.

In the process flow of the imprint device 1 described above, the fourth irradiation step is performed before the first irradiation step in S107. Here, the fourth irradiation step may be performed before the first irradiation step. In this case, since the temperature conditions of the wafer 11 change from those of the process flow described above, it is preferable to change the settings in advance.

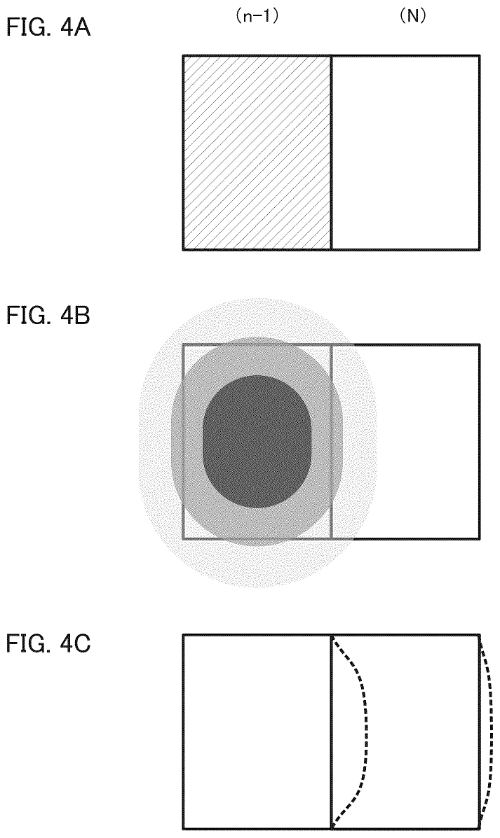

Here, the problems with the imprint process in the related art will be explained with reference to FIG. 4. FIG. 4 is a diagram for explaining the fact that the ultraviolet light 9 which cures the imprint material 14 affects the shape of the adjacent imprint regions. The solid lines in FIG. 4 indicate the imprint regions.

In the imprint process, since the pattern of the mold 8 is transferred to each of the plurality of imprint regions on the wafer 11, steps S104 to S108 are repeatedly performed. For this reason, it is assumed that an imprint region (n−1) which is subjected to the imprint process exists before a target imprint region (n) which is subjected to the imprint process. At this time, when the imprint process of the target imprint region (n) starts, the imprint process of the imprint region (n−1) is already performed. That is to say, the wafer 11 has already been irradiated with ultraviolet light 9 using the curing light irradiation unit 2 in the imprint region (n−1). A state in which the imprint region (n−1) is aligned with the imprint region and is irradiated with the ultraviolet light 9 is shown (hatched portion). Hereinafter, in the embodiment, the target imprint region which is subjected to the imprint process is referred to as the imprint region (n) and the target imprint region which is subjected to the imprint process before that is referred to as the imprint region (n−1).

Although the ultraviolet light 9 cures the imprint material 14, at the same time, the ultraviolet light 9 is transmitted through the imprint material 14 and reaches the wafer 11 and causes the wafer 11 to expand using the absorption heat thereof. Furthermore, even if only the imprint region which is subjected to the imprint process is irradiated, as shown in FIG. 4B, the heat absorbed by the wafer diffuses in the wafer 11, forming a temperature gradient in the adjacent imprint regions (n) as well. The contour diagram shown in FIG. 4B shows a temperature distribution of the wafer 11 after the imprint region (n−1) in FIG. 4A is irradiated with the ultraviolet light 9 and the darker the color, the higher the temperature. As a result, the shape of the imprint region (n) may also change as shown in FIG. 4C (for example, may change as shown by the dotted line).

As described above, the heating mechanism 60 acquires information regarding the difference in shape using an external measurement device and the control unit 7 calculates an illuminance distribution which reduces the difference in shape. Here, this information regarding the difference in shape already also includes the influence of the previous imprint region (n−1) described above.

On the other hand, if it is determined that the imprint region (n−1) is a skip region in S103, the adjacent target imprint region (n) which is subjected to the imprint process will not be deformed. That is to say, in accordance with whether the previous imprint region (n−1) is skipped, it may be difficult to maintain the mold 8 and the wafer 11 in the target imprint region (n) which overlap with high accuracy.

In order to reduce this influence, in the embodiment, if it is determined in S103 that the region is a skip region, the above skip processes (S105′ to S108′) are performed. By reproducing the irradiation conditions using the ultraviolet light 9 and the correction conditions of the heating mechanism 60 in the skip region, wafer deformation in the target imprint region (n) can be generated even if the previous imprint region (n−1) is skipped. That is to say, stable overlapping accuracy can be obtained even if the imprint region to be skipped through foreign particle inspection changes dynamically for each wafer.

In the embodiment, a case in which the dummy stamping is performed in S105′ and the dummy demolding is performed in S108′ is explained. This is because, taking into consideration the thermal conduction of the absorption heat of the wafer 11 caused due to the dummy exposure performed in S105′, it is preferable for the wafer 11 and the mold 8 to be in close proximity to each other in the same state as if the imprint process were performed.

Here, if the gap between the wafer 11 and the mold 8 is too narrow, the patterns on the wafer 11 and the mold 8 are likely to be damaged due to contact without the imprint material 14 present. For this reason, it is preferable that the gap between the wafer 11 and the mold 8 be a gap of about 5 μm to 50 μm. Furthermore, the gap between the wafer 11 and the mold 8 may be determined on the basis of the size of the foreign particle detected using a foreign particle inspection device. For example, if a particle size of a foreign particle detected using a foreign particle inspection device is 1 μm, the gap between the wafer 11 and the mold 8 can be set to 5 μm, thereby preventing contact between the mold 8 and the foreign particle.

Also, a light-shielding film (for example, a metal film) which blocks the ultraviolet light 9 is provided outside of the imprint region on an outer circumference of the pattern portion 8a of the mold 8 in some cases. In this case, it is preferable that the gap between the wafer 11 and the mold 8 be as close described above, taking into consideration the region on which the light-shielding film is formed as well. This is because the range of light reaching the imprint region on the wafer 11 changes in accordance with a distance between the mold 8 and the wafer 11 on which the light-shielding film is formed and the temperature distribution due to absorption heat thereof and even the amount of deformation can also change. Thus, it is preferable to perform a dummy exposure in S107′ under conditions similar to those during the exposure process in S107 (first exposure step).

Also, it is described in the embodiment that the wafer chuck 19 partially decreases the pressure value of the suction units with respect to a region corresponding to the imprint region simultaneously or in conjunction with the dummy demolding of S108′. This is because the amount of deformation of the wafer 11 caused due to the irradiation with the ultraviolet light 9 is affected by the friction occurring between the wafer 11 and the wafer chuck 19, and thus it is preferable to use the same friction as when performing the imprint process. That is to say, it is preferable to partially decrease the pressure value of the suction units with respect to a region corresponding to the imprint region which is subjected to a dummy exposure and to adsorb a region other than the region which is subjected to a dummy exposure onto the wafer chuck 19 with a pressure the same as that of S108. Thus, the deformation to the target imprint region (n) of the imprint process through the dummy exposure can be made the same as that during the imprint process. In addition to that, the pressure value of the suction units corresponding to the imprint region (n) which is subjected to the dummy exposure may be partially increased.

Even if the suction pressure of the wafer chuck 19 is not decreased at the same time as the dummy demolding operation, light of an illuminance sufficient to cause deformation occurring beyond the maximum static friction force acting between the wafer 11 and the wafer chuck 19 may be radiated. That is to say, irradiation may be performed by setting the illuminance of the ultraviolet light 9 that is second light to the illuminance which causes deformation exceeding that of a friction force between the wafer 11 and the wafer chuck 19 (a substrate holding unit) which holds the wafer 11. In this case, it is preferable that a relationship between the illuminance of the ultraviolet light 9, the pressure applied to the wafer 11, and the deformation of the wafer 11 be calculated in advance and the pressure and the illuminance in which the amount of deformation which occurs during the actual imprint process is conceived be set. Thus, even if the suction pressure of the wafer chuck 19 is not decreased, deformation which is the same as that of the imprint process can be produced.

As described above, in S111′, the wafer 11 which has been subjected to the skip process (S105′ to S108′) described above is stored in another wafer storage case which is different from a normal wafer storage case and the skip region is subjected to the imprint process using another mold for which it will not be a problem if it breaks later.

As described above, according to the imprint method of the imprint device 1 in the first embodiment, even if a region which is not subjected to the imprint process (skip region) exists, it is possible to form patterns while maintaining the overlapping accuracy well.

### Second Embodiment

An imprint method in an imprint device 1 of a second embodiment will be described below. In the second embodiment as well, a device configuration, a method of an imprint process, and the like are the same as those in the first embodiment. Thus, only constituent elements which are different from those of the first embodiment will be explained below and explanations of the same constituent elements will be omitted.

Although the ultraviolet light 9 that is light having a wavelength which cures an imprint material has been used in the dummy exposure (second irradiation step) of S107′ in the first embodiment, the second embodiment is characterized by using the light 62 provided in the heating mechanism 60. That is to say, in the second embodiment, in the dummy exposure in S107′, the control unit 7 controls the heating mechanism 60 to radiate the light 62 that is third light, instead of the ultraviolet light 9 that is second light.

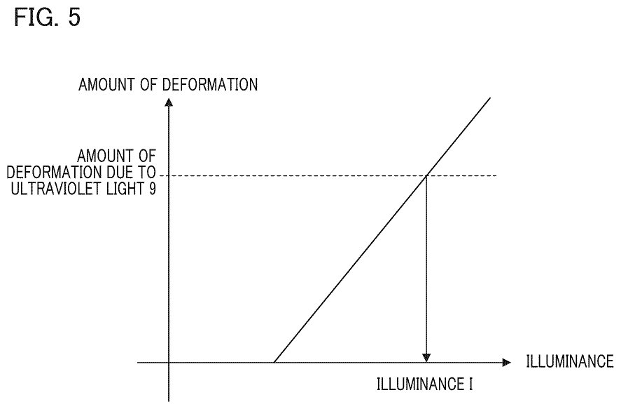

FIG. 5 is a diagram for explaining an example of a method for calculating the illuminance of light 62 provided in a heating mechanism 60. In the embodiment, first, the deformation of an imprint region (n) which is subjected to an imprint process when an imprint region (n−1) before the imprint process is performed is irradiated with ultraviolet light 9 is obtained in advance. This can confirm that, for example, the overlay results of the imprint region (n) are each measured using an external measuring device when the previous imprint region (n−1) has been subjected to the imprint process and when the previous imprint region (n−1) has not been subjected to the imprint process and the difference is calculated.

Subsequently, as shown in FIG. 5, a relationship between the illuminance of the light 62 and the deformation of an imprint region, and in Step S107′, the light 62 is radiated with an illuminance I which produces deformations which is the same as those produced using the ultraviolet light 9. The illuminance distribution of the light 62 on the wafer 11 is an illuminance distribution which is uniform across the entire imprint region, as in that of the ultraviolet light 9.

Furthermore, regardless of the above example, for example, the illuminance may be determined from a ratio of the wavelength dependence of the ultraviolet light 9 and the light 62 on the wafer 11.

Here, an example of the effect of using the light 62 provided in the heating mechanism 60 in the dummy exposure in S107′ will be described. For example, in the first embodiment, it has been described that the coating of the imprint material is performed in S104 (coating step) immediately before imprinting. Here, if a wafer which has already been coated with an imprint material is subjected to the imprint process, the ultraviolet light 9 cannot be radiated in the skip region. This is because, in the case of a wafer which has already been coated with an imprint material, if the skip region also has already been coated with the imprint material and is irradiated with the ultraviolet light 9, the imprint material on the skip region is cured. In this state, it will no longer be possible to subject the skip region to the imprint process using another mold for which it will not be problem if it breaks later. In this case, if the light is the light 62 provided in the heating mechanism 60, instead of the ultraviolet light 9, the light is light with a wavelength which does not cure the imprint material. Thus, the wafer 11 can be deformed through a dummy exposure without curing the imprint material.

As described above, according to the imprint method of the imprint device 1 in the second embodiment, even if a region which is subjected to imprint exists in the case of a coated wafer, as in the first embodiment, it is possible to form a pattern while maintaining the overlapping accuracy well.

### Example of Article Manufacturing Method

The method for manufacturing an article according to the embodiment is suitable for, for example, manufacturing an article such as micro-devices such as semiconductor devices and elements having fine structures. The method for manufacturing an article of the embodiment includes a step of forming a pattern on a composition with which a substrate is coated using the imprint device 1 and a step of processing the substrate on which the pattern has been formed through such a step. In addition, such a manufacturing method includes other well-known steps (oxidation, film formation, deposition, doping, planarization, etching, composition stripping, dicing, bonding, packaging, and the like). The method for manufacturing an article according to this embodiment is advantageous in at least one of the performance, the quality, productivity, and the production cost of the article as compared to methods in the related art.

A pattern of a cured material formed using the imprint device 1 can be used permanently on at least a part of various articles or temporarily during the manufacturing of various articles. The article is an electric circuit element, an optical element, a MEMS, a recording element, a sensor, a mold (a mould), or the like. As the electric circuit element, there are volatile or non-volatile semiconductor memories such as DRAMs, SRAMs, flash memories, and MRAMs, semiconductor elements such as LSIs, CCDs, image sensors, and FPGAs, and the like. As the mold, there are molds and the like for processing a substrate such as imprinting.

The pattern of the cured material may be used as is or may be used temporarily as a composition mark, as a configuration member of at least a part of the article. During the substrate process, after etching, ion implantation, or the like, a composition mark is removed.

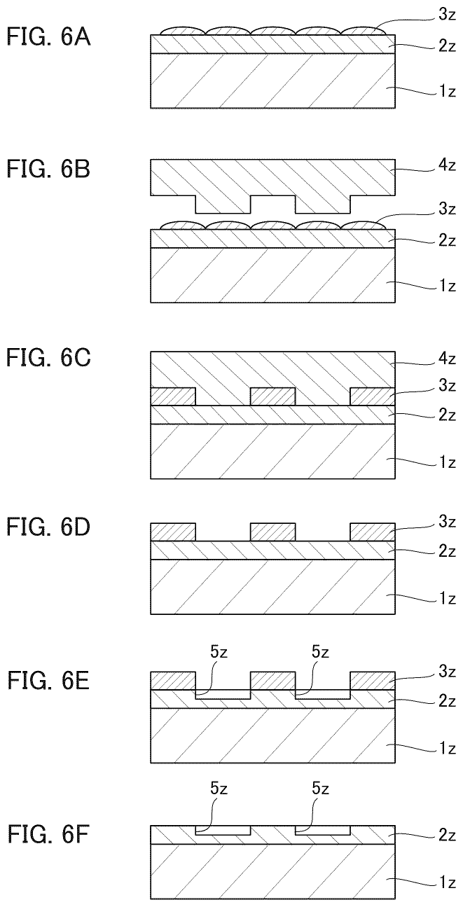

A specific method for manufacturing an article will be described below with reference to FIG. 6. As shown in FIG. 6A, a substrate 1z such as a silicon substrate having a workpiece 2z such as an insulator formed on a surface thereof is prepared, and then a composition 3z is provided to the surface of the workpiece 2z through an ink-jet method or the like. Here, a state in which a plurality of droplets of the composition 3z are provided onto the substrate 1z is shown.

As shown in FIG. 6B, a mold 4z faces the composition 3z on the substrate 1z so that a side thereof on which a concave and convex pattern thereof is formed faces the composition 3z on the substrate 1z. As shown in FIG. 6C, the substrate 1z to which the composition 3z is provided is brought into contact with the mold 4z and is subjected to pressure (contact step). A gap between the mold 4z and the workpiece 2z is filled with the composition 3z. In this state, when light as curing energy is radiated through the mold 4z, the composition 3z is cured (curing step). At this time, in the embodiment, based on the spectral sensitivity characteristics obtained in the device, it is possible to irradiate the composition with light at an amount of irradiation which will result in an optimal degree of photopolymerization.

As shown in FIG. 6D, if the mold 4z and the substrate 1z are separated after the composition 3z is cured, a pattern of the cured material of the composition 3z is formed on the substrate 1z (pattern formation step, molding step). The pattern of this cured material has a shape in which a concave portion of the mold 4z corresponds to the convex portion of the cured material and a convex portion of mold 4z corresponds to the concave portion of the cured material. That is to say, the concave and convex pattern of the mold 4z has been transferred to the composition 3z.

As shown in FIG. 6E, if etching is performed using the pattern of the cured material as an etching-resistant mask, the portions of the surface of the workpiece 2z in which there is no cured material or in which only a thin layer of the cured material remains are removed, forming grooves 5z. As shown in FIG. 6F, if the pattern of the cured material is removed, an article having the grooves 5z formed on a surface of the workpiece 2z can be obtained. Here, although the pattern of the cured material has been removed, the pattern may be used as an interlayer insulating film included in a semiconductor element or the like, that is, as a constituent member of an article, without being removed after a process. As the mold 4z, although an example in which a mold for transferring a circuit pattern having a concave and convex pattern provided therein is used has been described, a flat template having a flat surface without a concave and convex pattern may also be used.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

This application claims the benefit of Japanese Patent Application No. 2024-075400, filed on May 7, 2024, which is hereby incorporated by reference wherein in its entirety.

What is claimed is:

1. An imprint method, comprising:
a contact step of bringing a mould into contact with an imprint material on a substrate;
a first irradiation step of irradiating the imprint material on the substrate with first light for curing the imprint material while the mould and the imprint material on the substrate are in contact with each other;
a demolding step of separating the mould from the imprint material on the substrate; and
a second irradiation step of irradiating, other than an imprint region in which an imprint process including the contact step, the first irradiation step, and the demolding step is performed, a skip region that is a region in which the imprint process is skipped with second light if the skip region exists on the substrate.

2. The imprint method according to claim 1, comprising:
a first movement step of moving the mould close to the substrate before the second irradiation step; and
a second movement step of separating the mould from the substrate after the second irradiation step.

3. The imprint method according to claim 1, comprising:
a pressure control step of decreasing a suction pressure of the substrate after the second irradiation step.

4. The imprint method according to claim 1, wherein the second light radiated in the second irradiation step is light having a wavelength which cures the imprint material.

5. The imprint method according to claim 1, wherein an irradiation time of the second light and a wavelength, an illuminance, and an illuminance distribution of the second light in the second irradiation step are almost the same as those in the first irradiation step.

6. The imprint method according to claim 2, comprising:
a third irradiation step of irradiating the imprint material with third light having a wavelength which does not cure the imprint material after the first movement step and before the second irradiation step.

7. The imprint method according to claim 1, wherein, in the second irradiation step, third light having a wavelength which does not cure the imprint material is radiated, instead of the second light.

8. The imprint method according to claim 6, wherein the third light is light having a wavelength for correcting a difference in shape between the imprint region on the substrate and a pattern portion on which a pattern is formed.

9. The imprint method according to claim 7, wherein the third light is light having a wavelength for correcting a difference in shape between the imprint region on the substrate and a pattern portion on which a pattern is formed.

10. The imprint method according to claim 6, comprising:
a fourth irradiation step of irradiating the imprint region with the third light having a wavelength for correcting a difference in shape between the imprint region on the substrate and a pattern portion on which a pattern is formed,
wherein an irradiation time of the third light radiated in the third irradiation step and a wavelength, an illuminance, and an illuminance distribution of the third light are almost the same as those in the fourth irradiation step.

11. The imprint method according to claim 1, wherein the illuminance of the second light is an illuminance which causes deformation exceeding that of a friction force between the substrate and a substrate holding unit which holds the substrate.

12. The imprint method according to claim 1, comprising:
a determination step for determining whether an imprint region which is to be subjected to the imprint process is the skip region,
wherein, in the determination step, an imprint region which is determined not to be the skip region is subjected to the contact step, the first irradiation step, and the demolding step in this order to form a pattern of the imprint material on the substrate.

13. The imprint method according to claim 12, wherein, in the determination step, it is determined whether a region is a skip region on the basis of information regarding a foreign particle on the imprint region.

14. The imprint method according to claim 1, wherein the skip region is a region which is not coated with the imprint material.

15. An imprint device, comprising:
an irradiation unit which irradiates an imprint material on a substrate with first light for curing the imprint material while the mould and the imprint material on the substrate are in contact with each other; and
a control unit which controls, if a skip region that is a region in which an imprint process is skipped exists on the substrate, other than a plurality of imprint regions which are subjected to the imprint process, light radiated from the irradiation unit to irradiate the skip region with second light.

16. The imprint device according to claim 15, wherein the imprint process includes irradiating, by the irradiation unit, the imprint material on the substrate with the first light for curing the imprint material while the mould and the imprint material on the substrate are in contact with each other, and separating the mould from the imprint material on the substrate.

17. An article manufacturing method, comprising:
forming a pattern on a substrate using an imprint device;
processing the substrate on which the pattern is formed in the forming; and
manufacturing an article from the substrate processed in the processing,
wherein the imprint device includes:
an irradiation unit which irradiates an imprint material on the substrate with first light for curing the imprint material while the mould and the imprint material on the substrate are in contact with each other; and
a control unit which controls, if a skip region that is a region in which the imprint process is skipped exists on the substrate, other than a plurality of imprint regions which are subjected to an imprint process, light radiated from the irradiation unit to irradiate the skip region with second light.
